(19) United States
(12) Patent Application Publication
(10) Pub. No.: US 2019/0088512 A1
(43) Pub. Date: Mar. 21, 2019

(54) Cooled Focus Ring for Plasma Processing Apparatus

(71) Applicant: Mattson Technology, Inc., Fremont, CA (US)

(72) Inventor: Martin L. Zucker, Orinda, CA (US)

(21) Appl. No.: 16/103,100

(22) Filed: Aug. 14, 2018

Related U.S. Application Data
(60) Provisional application No. 62/559,778, filed on Sep. 18, 2017.

(51) Int. Cl. H01L 21/67; H01J 37/32; H01L 21/683

(52) U.S. Cl. CPC H01L 21/67069; H01J 2237/2001; H01L 21/6831; H01J 37/32642

(57) ABSTRACT

A pedestal assembly for use in a plasma processing apparatus for processing a substrate includes a baseplate. The pedestal assembly can further include a puck configured to support a substrate. The pedestal assembly can further include a focus ring arranged relative to the puck such that at least a portion of the focus ring at least partially surrounds a periphery of the substrate when the substrate is positioned on the puck. In addition, the focus ring can be spaced apart from the puck so that a gap is defined therebetween. The pedestal assembly can further include a thermally conductive member spaced apart from the puck. The thermally conductive member can be in thermal communication with the focus ring surrounded by the inner insulator ring and configured to be in thermal communication with the focus ring and the baseplate.

### PRIORITY CLAIM

The present application claims the benefit of priority of U.S. Provisional Patent Application Ser. No. 62/559,778, filed Sep. 18, 2017, titled “Cooled Focus Ring for Plasma Processing Apparatus,” which is incorporated herein by reference for all purposes.

### FIELD

The present disclosure relates generally to focus rings used in, for instance, a processing apparatus for processing substrates, such as semiconductor substrates.

### BACKGROUND

Plasma processing tools can be used in the manufacture of devices such as integrated circuits, micromechanical devices, flat panel displays, and other devices. Plasma processing tools used in modern plasma etch applications can be required to provide a high plasma uniformity and a plurality of plasma controls, including independent plasma profile, plasma density, and ion energy controls. Plasma processing tools can, in some cases, be required to sustain a stable plasma in a variety of process gases and under a variety of different conditions (e.g. gas flow, gas pressure, etc.).

Pedestal assemblies can be used to support substrates in a plasma processing apparatus and other processing tools (e.g., thermal processing tools). Pedestal assemblies can include insulator rings that surround pedestal baseplate(s). A focus ring can be used in conjunction with pedestal assemblies in plasma processing tools. During processing of a substrate (e.g., semiconductor wafer), the focus ring can be in an environment (e.g., a vacuum) in which it is difficult to remove heat. As such, cooling the focus ring during processing of the substrate can be difficult. However, inadequately cooling the focus ring can adversely affect a lifespan of the focus ring, which is generally undesirable.

### SUMMARY

Aspects and advantages of the disclosure will be set forth in part in the following description, or may be obvious from the description, or may be learned through practice of the embodiments.

One example aspect of the present disclosure is directed to a pedestal assembly for use in a plasma processing apparatus for processing a substrate. The pedestal assembly can include a baseplate and a puck configured to support the substrate. In addition, the pedestal assembly can include a focus ring arranged relative to the puck such that at least a portion of the focus ring at least partially surrounds a periphery of the substrate when the substrate is positioned on the puck. The focus ring can also be spaced apart from the puck so that a gap is defined therebetween. In addition, the pedestal assembly can also include a thermally conductive member spaced apart from the puck. The thermally conductive member can be in thermal communication with both the focus ring and the baseplate.

Other aspects of the present disclosure are directed to systems, methods, apparatus, and devices for cooling a focus ring used in processing tools for substrates, such as semiconductor substrates.

These and other features, aspects and advantages of the present disclosure will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure to one of ordinary skill in the art is set forth more particularly in the remainder of the specification, including reference to the accompanying figures, in which:

FIG. 1 depicts an example plasma processing apparatus according to example embodiments of the present disclosure;

FIG. 2 provides a cross-sectional view of a portion of the example pedestal assembly depicted in FIG. 1;

FIG. 3 provides a cross-sectional view of a baseplate according to example embodiments of the present disclosure;

FIG. 4 provides a cross-sectional view of a focus ring according to example embodiments of the present disclosure;

FIG. 5 provides a close-up view of a portion of a pedestal assembly according to example embodiments of the present disclosure;

FIG. 6 provides a close-up view of a portion of a pedestal assembly according to example embodiments of the present disclosure; and

FIG. 7 provides a cross-sectional view of a portion of an example pedestal assembly according to example embodiments of the present disclosure.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Example aspects of the present disclosure are directed to pedestal assemblies for use in conjunction with a processing apparatus, such as a plasma processing apparatus (e.g., a plasma etcher). A plasma processing apparatus can include a processing chamber defining an interior space. A pedestal assembly can be located within the processing chamber. The pedestal assembly can include a puck (e.g., electrostatic chuck) configured to support a substrate (e.g., semiconductor wafer) during plasma processing. The pedestal assembly can also include a focus ring that surrounds the periphery of the substrate on the puck and can be used, for instance, to reduce non-uniformity in the plasma process (e.g., etch rate) at or near the periphery of the substrate.

The pedestal assembly can also include a baseplate. The baseplate can define one or more passages through which a fluid (e.g., water) flows to reduce (e.g., cool) a temperature of the baseplate. The focus ring can be thermally coupled to the baseplate via a thermally conductive member that promotes thermal communication (e.g., heat transfer) between the focus ring and the baseplate structure. More specifically, heat from the focus ring can be transferred from the focus ring to the baseplate via the thermally conductive member.

In some embodiments, the pedestal assembly can include a first thermal pad and a second thermal pad. The first thermal pad can be positioned between the focus ring and the thermally conductive member. The second thermal pad can be positioned between the thermally conductive member and the baseplate. The first thermal pad can be formed from a resilient material to provide good thermal contact between the focus ring and thermally conductive member. The second thermal pad can be formed from a resilient material to provide good thermal contact between the thermally conductive member and the baseplate. As used herein, a resilient material is any material capable of at least partially returning to an original shape after deformation (e.g., bending, stretching, compression, etc.). For example, in some embodiments, the first thermal pad and/or the second thermal pad can be an adhesive tape. In this way, the first thermal pad can improve heat transfer from the focus ring to the thermally conductive member, and the second thermal pad can promote heat transfer from the thermally conductive member to the baseplate.

In some embodiments, the focus ring can have a shape adapted to improve thermal transfer of heat through the thermally conductive member to the baseplate. For instance, the focus ring can have a stepped bottom surface. A portion of the bottom surface can be in contact with the first thermal pad to provide a thermal connection with the thermally conductive member.

The focus ring can have a shape and configuration such that the focus ring is not in contact with the puck. For instance, the focus ring can have a body and a protrusion extending from the body. The protrusion and the puck can define a gap so that the focus ring does not contact the puck. In this way, a primary conductive heat path is provided for conduction of heat between the focus ring and the baseplate through the first thermal pad, the thermally conductive member, and the second conductive pad.

Example aspects of the present disclosure can have a number of technical effects and benefits. For instance, providing a primary conductive heat path with a temperature regulated baseplate can provide for more precise thermal control of the focus ring. In addition, use of a resilient thermal pad can assist with making good thermal contact between the focus ring and the thermally conductive member in harsh environments, such as in a plasma processing apparatus.

One example aspect of the present disclosure is directed to A pedestal assembly for use in a plasma processing apparatus for processing a substrate. The pedestal assembly includes a baseplate. The pedestal assembly includes a puck configured to support the substrate. The pedestal assembly includes a focus ring arranged relative to the puck such that at least a portion of the focus ring at least partially surrounds a periphery of the substrate when the substrate is positioned on the puck. The pedestal assembly includes a thermally conductive member spaced apart from the puck, the thermally conductive member in thermal communication with the focus ring and the baseplate. The puck and the focus ring define a gap therebetween.

In some embodiments, the focus ring includes a protrusion that extends at least partially overlapping the puck. The protrusion of the focus ring can be disposed between at least a portion of the substrate and at least a portion of the puck when the substrate is supported on the puck. The protrusion can be integrally formed with a body of the focus ring.

In some embodiments, the pedestal assembly further includes a first thermal pad and a second thermal pad. The first thermal pad can be in contact with the focus ring and the thermally conductive member. The second thermal pad can be in contact with the thermally conductive member and the baseplate. In some embodiments, the first thermal pad and the second thermal pad include a resilient material, such as an adhesive tape.

In some embodiments, a thermal conductivity of the first thermal pad can be different than a thermal conductivity of the second thermal pad. In some embodiments, a thermal conductivity of the thermally conductive member can be different than the thermal conductivity of the first thermal pad or the thermal conductivity of the second thermal pad. In some embodiments, the pedestal assembly can include a fastener configured to provide a compression connection that compresses the second thermal pad between the thermally conductive member and the baseplate.

In some embodiments, the pedestal assembly includes an inner insulator ring at least partially surrounding the thermal conductive member and the baseplate. In some embodiments, the baseplate can define one or more passages through which a fluid flows to adjust a temperature of the baseplate. In some embodiments, the thermally conductive member is a ring that includes aluminum.

In some embodiments, the baseplate can be stepped such that the baseplate comprises a first portion that extends vertically above a second portion. The puck can be disposed above the first portion of the baseplate. In some embodiments, the second thermal pad can be in contact with the second portion of the baseplate.

Another example aspect of the present disclosure is directed to a plasma processing apparatus for processing a substrate. The apparatus can include a processing chamber defining an interior space. The apparatus can include a pedestal assembly disposed within the interior space. The pedestal assembly can include an inner insulator ring. The pedestal assembly can include a baseplate surrounded at least in part by the inner insulator ring. The pedestal assembly can include a puck configured to support the substrate. The pedestal assembly can include a focus ring at least partially surrounding a periphery of the substrate when the substrate is positioned on the puck. The focus ring can include a top surface and an opposing bottom surface. The pedestal assembly can include a first thermal pad in contact with the bottom surface of the focus ring. The pedestal assembly can include a second thermal pad in contact with the baseplate. The pedestal assembly can include a thermally conductive member coupled between the first thermal pad and the second thermal pad. The first thermal pad, second thermal pad, and thermally conductive member can form a heat path for conduction of heat from the focus ring to the baseplate. The focus ring can have a body and a protrusion extending from the body. The protrusion can be disposed between the substrate and the puck when the substrate is supported by the puck. A gap can be defined between the puck and the protrusion of the substrate.

In some embodiments, the first thermal pad and the second thermal pad comprise a resilient material. In some embodiments, the baseplate can be stepped such that the baseplate comprises a first portion that extends vertically above a second portion. The puck can be disposed above the first portion of the baseplate; and wherein the second thermal pad is in contact with the second portion of the baseplate. In some embodiments, the pedestal assembly can include a fastener configured to provide a compression connection that compresses the second thermal pad between the thermally conductive member and the baseplate.

Aspects of the present disclosure are discussed with reference to a “substrate” or “wafer” for purposes of illustration and discussion. Those of ordinary skill in the art, using the disclosures provided herein, will understand that the example aspects of the present disclosure can be used in association with any semiconductor substrate or other suitable substrate or workpiece. In addition, the use of the term “about” in conjunction with a numerical value is intended to refer to within 10% of the stated numerical value.

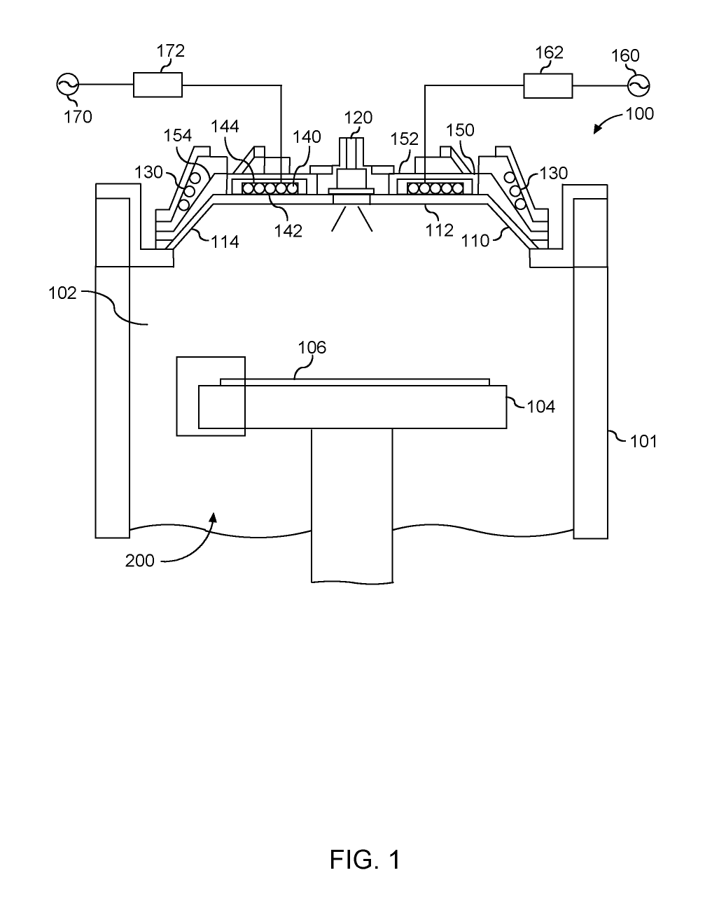

FIG. 1 depicts a plasma processing apparatus 100 according to example embodiments of the present disclosure. The present disclosure is discussed with reference to the plasma processing apparatus 100 depicted in FIG. 1 for purposes of illustration and discussion. Those of ordinary skill in the art, using the disclosures provided herein, will understand that example aspects of the present disclosure can be used with other processing tools and/or apparatus without deviating from the scope of the present disclosure, such as plasma strip tools, thermal processing tools, etc.

The plasma processing apparatus 100 includes a processing chamber 101 defining an interior space 102. A pedestal assembly 104 is used to support a substrate 106, such as a semiconductor wafer, within the interior space 102. A dielectric window 110 is located above the pedestal assembly 104 and acts as a ceiling of the interior space 102. The dielectric window 110 includes a relatively flat central portion 112 and an angled peripheral portion 114. The dielectric window 110 includes a space in the central portion 112 for a showerhead 120 to feed process gas into the interior space 102.

The plasma processing apparatus 100 further includes a plurality of inductive elements, such as primary inductive element 130 and secondary inductive element 140, for generating an inductive plasma in the interior space 102. The inductive elements 130, 140 can include a coil or antenna element that when supplied with RF power, induces a plasma in the process gas in the interior space 102 of plasma processing apparatus 100. For instance, a first RF generator 160 can be configured to provide electromagnetic energy through a matching network 162 to the primary inductive element 130. A second RF generator 170 can be configured to provide electromagnetic energy through a matching network 172 to the secondary inductive element 140.

While the present disclosure makes reference to a primary inductive element and a secondary inductive element, those of ordinary skill in the art, should appreciate that the terms primary and secondary are used for convenience purposes only. The secondary coil can be operated independently of the primary coil. The primary coil can be operated independently of the secondary coil. In addition, in some embodiments, the plasma processing apparatus may only have a single inductive coupling element.

According to aspects of the present disclosure, the plasma processing apparatus 100 can include a metal shield portion 152 disposed around the secondary inductive element 140. The metal shield portion 152 separates the primary inductive element 130 and the secondary inductive element 140 to reduce cross-talk between the inductive elements 130, 140. The plasma processing apparatus 100 can further include a first Faraday shield 154 disposed between the primary inductive element 130 and the dielectric window 110. The first Faraday shield 154 can be a slotted metal shield that reduces capacitive coupling between the primary inductive element 130 and the process chamber 101. As illustrated, the first Faraday shield 154 can fit over the angled portion of the dielectric window 110.

In some embodiments, the metal shield 152 and the first Faraday shield 154 can form a unitary body 150 for ease of manufacturing and other purposes. The multi-turn coil of the primary inductive element 130 can be located adjacent the Faraday shield portion 154 of the unitary body metal shield/Faraday shield 150. The secondary inductive element 140 can be located proximate the metal shield portion 152 of metal shield/Faraday shield unitary body 150, such as between the metal shield portion 152 and the dielectric window 110.

The arrangement of the primary inductive element 130 and the secondary inductive element 140 on opposite sides of the metal shield 152 allows the primary inductive element 130 and secondary inductive element 140 to have distinct structural configurations and to perform different functions. For instance, the primary inductive element 130 can include a multi-turn coil located adjacent a peripheral portion of the process chamber 101. The primary inductive element 130 can be used for basic plasma generation and reliable start during the inherently transient ignition stage. The primary inductive element 130 can be coupled to a powerful RF generator and expensive auto-tuning matching network and can be operated at an increased RF frequency, such as at about 13.56 MHz.

The secondary inductive element 140 can be used for corrective and supportive functions and for improving the stability of the plasma during steady state operation. Since the secondary inductive element 140 can be used primarily for corrective and supportive functions and improving stability of the plasma during steady state operation, the secondary inductive element 140 does not have to be coupled to as powerful an RF generator as the primary inductive element 130 and can be designed differently and cost effectively to overcome the difficulties associated with previous designs. As discussed in detail below, the secondary inductive element 140 can also be operated at a lower frequency, such as at about 2 MHz, allowing the secondary inductive element 140 to be very compact and to fit in a limited space on top of the dielectric window.

The primary inductive element 130 and the secondary inductive element 140 can be operated at different frequencies. The frequencies can be sufficiently different to reduce cross-talk in the plasma between the primary inductive element 130 and the secondary inductive element 140. For instance, the frequency applied to the primary inductive element 130 can be at least about 1.5 times greater than the frequency applied to the secondary inductive element 140. In some embodiments, the frequency applied to the primary inductive element 130 can be about 13.56 MHz and the frequency applied to the secondary inductive element 140 can be in the range of about 1.75 MHz to about 2.15 MHz. Other suitable frequencies can also be used, such as about 400 kHz, about 4 MHz, and about 27 MHz. While the present disclosure is discussed with reference to the primary inductive element 130 being operated at a higher frequency relative to the secondary inductive element 140, those of ordinary skill in the art, using the disclosures provided herein, should understand that the secondary inductive element 140 could be operated at the higher frequency without deviating from the scope of the present disclosure.

The secondary inductive element 140 can include a planar coil 142 and a magnetic flux concentrator 144. The magnetic flux concentrator 144 can be made from a ferrite material. Use of a magnetic flux concentrator with a proper coil can give high plasma coupling and good energy transfer efficiency of the secondary inductive element 140, and can significantly reduce its coupling to the metal shield 150. Use of a lower frequency, such as about 2 MHz, on the secondary inductive element 140 can increase skin layer, which also improves plasma heating efficiency.

According to aspects of the present disclosure, the different inductive elements 130 and 140 can carry different functions. Specifically, the primary inductive element 130 can be used to carry out the basic functions of plasma generation during ignition and providing enough priming for the secondary inductive element 140. The primary inductive element 130 can have coupling to both plasma and the grounded shield to stabilize plasma potential. The first Faraday shield 154 associated with the primary inductive element 130 avoids window sputtering and can be used to supply the coupling to the ground.

Additional coils can be operated in the presence of good plasma priming provided by the primary inductive element 130 and as such, preferably have good plasma coupling and good energy transfer efficiency to plasma. A secondary inductive element 140 that includes a magnetic flux concentrator 144 provides both a good transfer of magnetic flux to plasma volume and at the same time a good decoupling of the secondary inductive element 140 from the surrounding metal shield 150. The use of magnetic flux concentrators 144 and symmetric driving of the secondary conductive element 140 further reduces the amplitude of the voltage between coil ends and surrounding grounded elements. This can reduce sputtering of the dome, but at the same time gives some small capacitive coupling to plasma, which can be used to assist ignition. In some embodiments, a second Faraday shield can be used in combination with this secondary inductive element 140 to reduce capacitive coupling of the secondary inductive element 140.

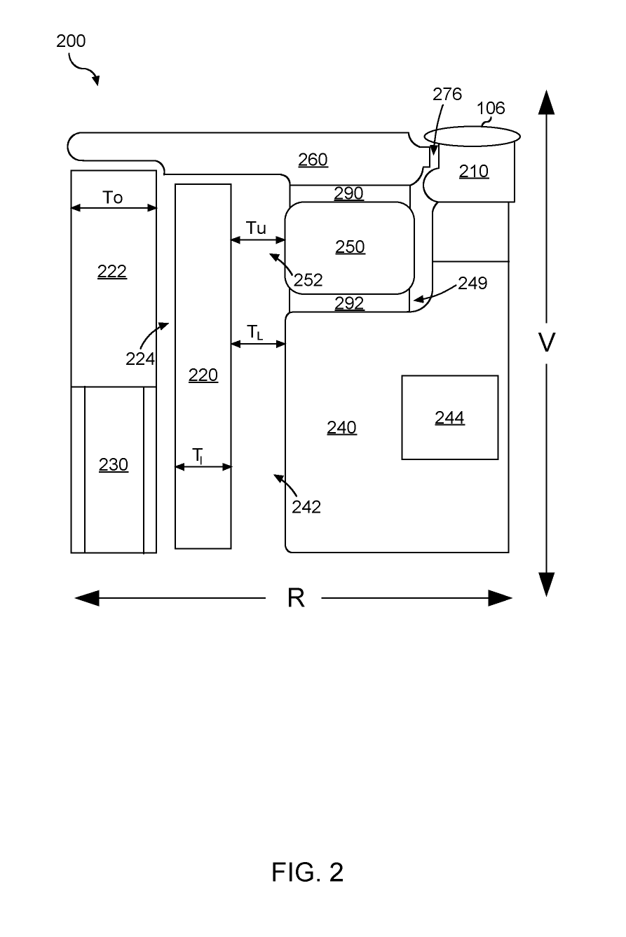

FIG. 2 depicts a close up view of a portion of the pedestal assembly corresponding to window 200 of FIG. 1. As shown, the pedestal assembly 104 can include a puck 210 configured to support the substrate 106, such as a semiconductor wafer. In some embodiments, the puck 210 can include an electrostatic chuck having one or more clamping electrodes configured to hold the substrate via an electrostatic charge. The puck 210 can also include a temperature regulation system (e.g., fluid channels, electric heaters, etc.) that can be used to control a temperature profile across the substrate 106.

As shown, the pedestal assembly 104 can include an inner insulator ring 220 and an outer insulator ring 222. More specifically, the outer insulator ring 222 can surround the inner insulator ring 220. In some embodiments, both the inner insulator ring 220 and the outer insulator ring 222 can surround at least a portion of the puck 210. In addition, the inner insulator ring 220 and the outer insulator ring 222 can be spaced apart from one another so that a gap 224 is defined therebetween along a radial direction R. Alternatively or additionally, the pedestal assembly 104 can include a clamp ring 230 on which the outer insulator ring 222 can be supported.

In some embodiments, a thickness T₁ of the inner insulator ring 220 can be different than a thickness T_{O} of the outer insulator ring 222. More specifically, the thickness T₁ of the inner insulator ring 220 can be less than or greater than the thickness T_{O} of the outer insulator ring 222. In alternative embodiments, however, the thickness T₁ of the inner insulator ring 220 and the thickness T_{O} of the outer insulator ring 222 can be equal to one another.

As shown, the pedestal assembly 104 can include a baseplate 240 configured to support the puck 210. In some embodiments, the baseplate 240 can be surrounded at least in part by the inner insulator ring 220. More specifically, the baseplate 240 and the inner insulator 220 can be spaced apart from one another so that a gap 242 is defined therebetween along the radial direction R. Alternatively or additionally, the baseplate 240 can define one or more passages 244 for a fluid to flow therethrough. When the fluid (e.g. water) enters the passage(s) 244, a temperature of the fluid can be cool relative to a temperature of the baseplate 240. However, as the fluid flows through the passage(s) 244, heat from the baseplate 240 can be transferred to the fluid. In this way, the temperature of the baseplate 240 can be lowered (e.g., cooled). As will be discussed below in more detail, flowing the fluid through the passage(s) 244 can cool one or more additional components of the pedestal assembly 104 that are in thermal communication (e.g., direct or indirect) with the baseplate 240.

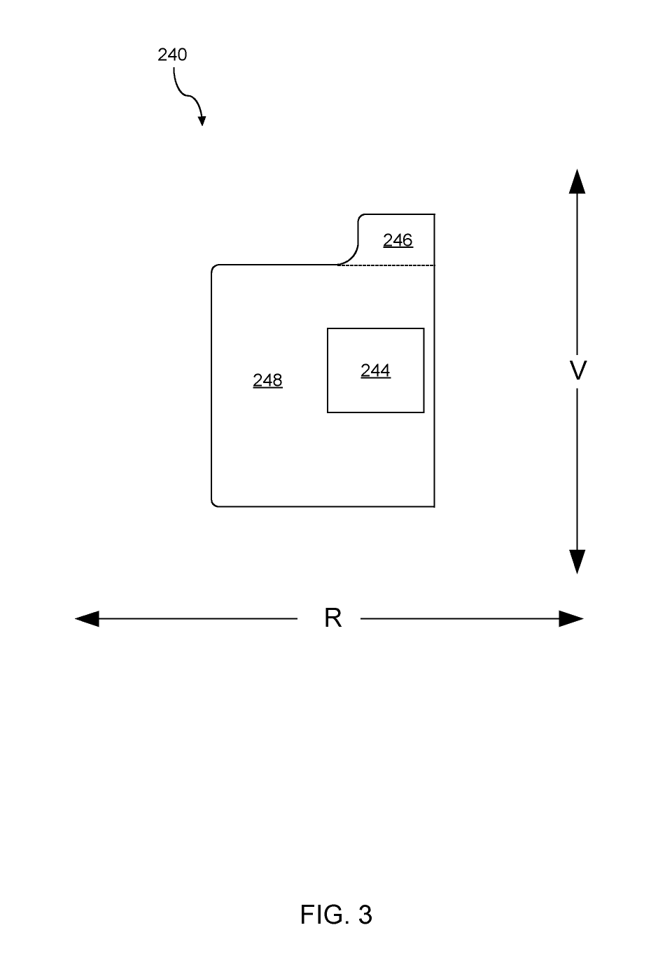

Referring now to FIGS. 2 and 3 in combination, the baseplate 240 can include a first portion 246 and a second portion 248. As shown, the first portion 246 can extend from the second portion 248 along a vertical direction V that is substantially orthogonal to the radial direction R. In some implementations, the puck 210 and the first portion 246 of the baseplate 240 can be spaced apart from one another along the vertical direction V.

The pedestal assembly 104 can also include a thermally conductive member 250 that is in thermal communication with the baseplate 240. In some embodiments, the thermally conductive member 250 can be supported by the baseplate 240 and surrounded by the inner insulator ring 220. More specifically, the thermally conductive member 250 and the inner insulator ring 220 can be spaced apart from one another so that a gap 252 is defined therebetween along the radial direction R. In some implementations, a thickness T_{U} of the gap 252 defined between the thermally conductive member 250 and the inner insulator ring 220 can be equal to a thickness T_{L} of the gap 242 defined between the baseplate 240 and the inner insulator ring 220. In this way, a uniform gap can be defined between the inner insulator ring 220 and both the baseplate 240 and the thermally conductive member 250.

It should be appreciated that the thermally conductive member 250 can be comprised of any suitable thermally conductive material. For instance, the thermally conductive member 250 can be a ring-shaped structure comprised of aluminum.

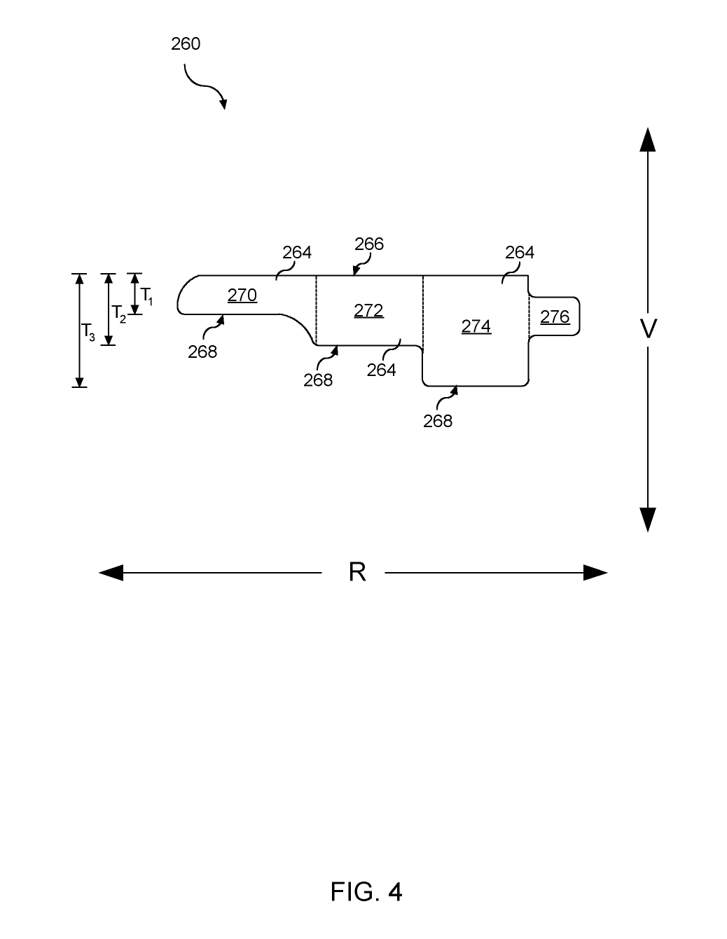

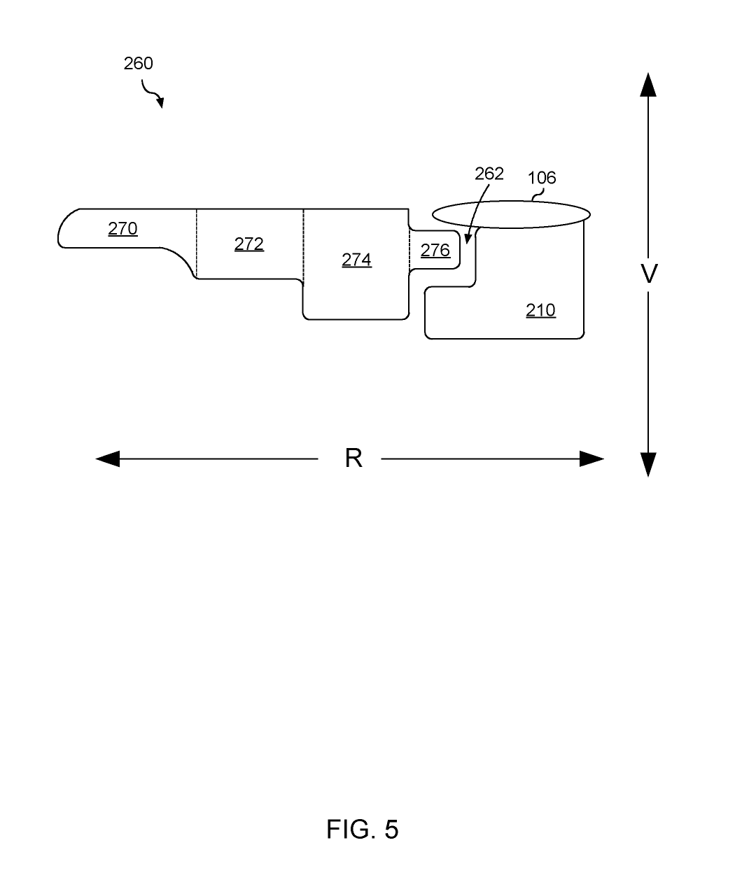

Referring now to FIGS. 2, 4 and 5 in combination, the pedestal assembly 104 can include a focus ring 260 that is in thermal communication with the thermally conductive member 250. In some implementations, the focus ring 260 can be arranged relative to the puck 210 so that at least a portion of the focus ring 260 at least partially surrounds a periphery of the substrate 106 when the substrate 106 is positioned on the puck 210. Alternatively or additionally, the puck 210 and the focus ring 260 can define a gap 262 therebetween.

As shown, the focus ring 260 can include a body 264 that extends between a top surface 266 and a bottom surface 268. In some implementations, the body 264 can include a first portion 270, a second portion 272, and a third portion 274. As shown, each of the first, second, and third portions 270, 272, 274 can extend between the top surface 266 and the bottom surface 268 along the vertical direction V. In some implementations, the first portion 270, the second portion 272, and the third portion 274 can each have a different thickness along the vertical direction V so that the bottom surface 268 is a stepped surface. For instance, a thickness T₁ of the first portion 270 can be less than a thickness T₂ of the second portion 272, and the thickness T₂ of the second portion 272 can be less than a thickness T₃ of the third portion 274. In this way, the bottom surface 268 can, as mentioned above, be a stepped surface that promotes heat transfer from the focus ring 260 to the thermally conductive member 250.

In some implementations, the second portion 272 of the body 264 can be spaced apart from the inner insulator ring 220 when the focus ring 260 is supported by the thermally conductive member 250. More specifically the second portion 272 can be spaced apart from the inner insulator ring 220 along the vertical direction V so that a gap 280 is defined therebetween. In addition, the first portion 270 of the focus ring 260 can be spaced apart from the outer insulator ring 222 along the vertical direction V so that a gap 282 is defined therebetween.

As shown, the focus ring 260 can include a protrusion 276 that is integrally formed with the body 264 and extends along the radial direction R so that the protrusion 276 at least partially overlaps the puck 210. More specifically, the protrusion 276 can extend from the third portion 274 of the body 264 and can be disposed between at least a portion of the substrate 106 and at least a portion of the puck 210 when the substrate 106 is supported on the puck 210.

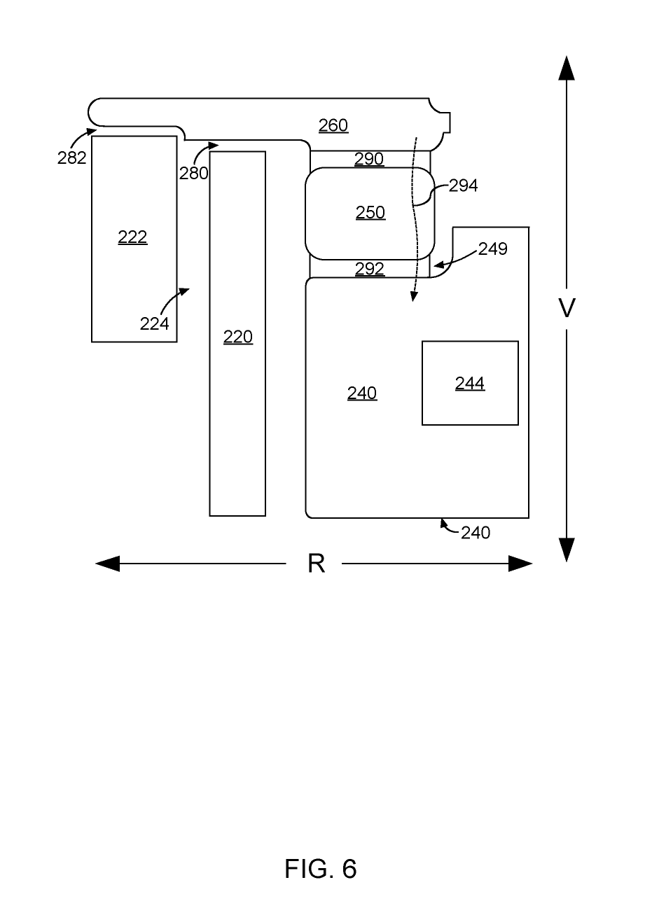

Referring now to FIGS. 2 through 6, the focus ring 260 can be supported by the thermally conductive member 250. More specifically, the bottom surface 268 of the focus ring 260 can contact (e.g., touch) the thermally conductive member 250. In alternative embodiments, however, the pedestal assembly 104 can include a first thermal pad 290 positioned between the thermally conductive member 250 and the focus ring 260. Alternatively or additionally, the pedestal assembly 104 can include a second thermal pad 292 positioned between the thermally conductive member 250 and the baseplate 240. In some implementations, the second thermal pad 292 can contact (e.g., touch) the second portion 248 of the baseplate 240 and can be spaced apart from the first portion 246 of the baseplate 240. More specifically, the second thermal pad 292 can be spaced apart from the first portion 246 along the radial direction R so that a gap 249 is defined therebetween.

In some implementations, the first thermal pad 290 and the second thermal pad 292 can be formed from any suitable resilient material. For example, the first thermal pad and the second thermal pad can include single-sided adhesive tape or double-sided adhesive tape.

It should be appreciated that a thermal conductivity k₁ of the first thermal pad 290 and a thermal conductivity k₂ of the second thermal pad 292 can include any suitable value. In some implementations, the thermal conductivity k₁ of the first thermal pad 290 can be different (e.g., greater than or less than) than the thermal conductivity k₂ of the second thermal pad 292. In alternative implementations, however, the thermal conductivity k₁ of the first thermal pad 290 and the thermal conductivity k₂ of the second thermal pad 292 can be equal to one another.

It should also be appreciated that a thermal conductivity k₃ of the thermally conductive member 250 can include any suitable value. In some implementations, the thermal conductivity k₃ of the thermally conductive member 250 can be different than the thermal conductivity k₁ of the first thermal pad 290, the thermal conductivity k₂ of the second thermal pad 292, or both. In alternative implementations, however, the thermal conductivity k₃ of the thermally conductive member 250 can be equal to the thermal conductivity k₁ of the first thermal pad 290, the thermal conductivity k₂ of the second thermal pad 292, or both.

Referring now to FIGS. 2-6, the focus ring 260 can be cooled when the fluid flows through the passages(s) 244 defined by the baseplate 240. As the fluid flows through the passage(s) 244, heat from the baseplate 240 can be transferred to the fluid. In addition, heat from the focus ring 260 can be transferred (e.g., via conduction) to the baseplate 240, because the first thermal pad 290, the thermally conductive member 250, and the second thermal pad 292 collectively define a heat path 294 for conduction of heat from the focus ring 260 to the baseplate 240. In this way, the focus ring 260 can be cooled during processing of the substrate 106.

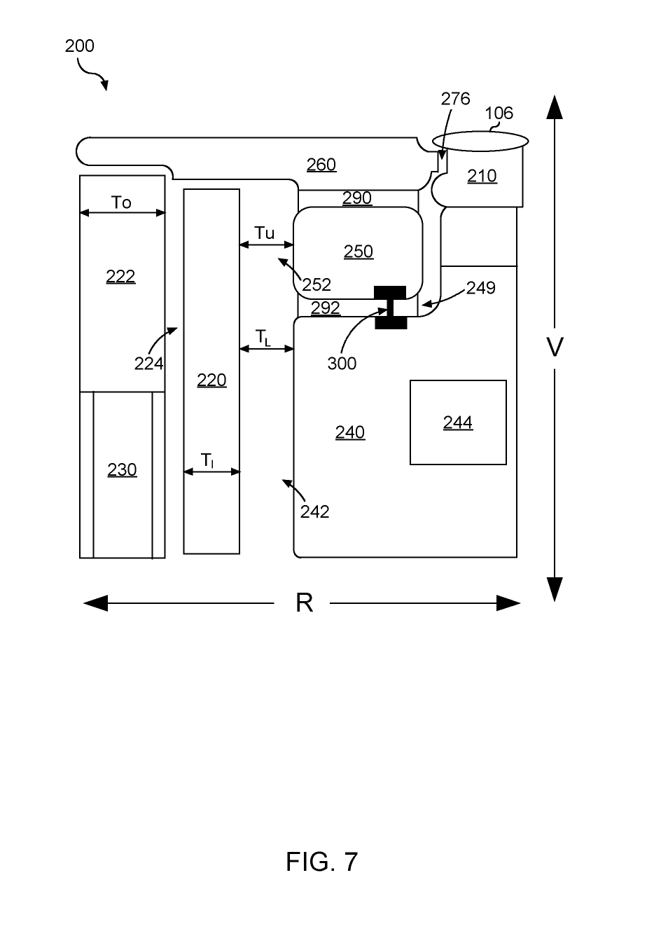

In some embodiments, as shown in FIG. 7, the pedestal assembly 104 can include a fastener 300 configured to provide a compression connection that compresses the second thermal pad 292 between the thermally conductive member 250 and the baseplate 240. In this way, the conduction of heat from the thermally conductive member 250 to the baseplate 240 can be improved. It should be appreciated that the fastener 300 can comprise any suitable fastener configured to provide the compression connection.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged in whole or in part. Furthermore, those of ordinary skill in the art will appreciate that the foregoing description is by way of example only, and is not intended to limit the invention so further described in such appended claims.

What is claimed is:

1. A pedestal assembly for use in a plasma processing apparatus for processing a substrate, the pedestal assembly comprising:
a baseplate;
a puck configured to support the substrate;
a focus ring arranged relative to the puck such that at least a portion of the focus ring at least partially surrounds a periphery of the substrate when the substrate is positioned on the puck; and
a thermally conductive member spaced apart from the puck, the thermally conductive member in thermal communication with the focus ring and the baseplate;
wherein the puck and the focus ring define a gap therebetween.

2. The pedestal assembly of claim 1, wherein the focus ring comprises a protrusion that extends at least partially overlapping the puck.

3. The pedestal assembly of claim 2, wherein the protrusion of the focus ring is disposed between at least a portion of the substrate and at least a portion of the puck when the substrate is supported on the puck.

4. The pedestal assembly of claim 2, wherein the protrusion is integrally formed with a body of the focus ring.

5. The pedestal assembly of claim 1, wherein the pedestal assembly further comprises a first thermal pad and a second thermal pad, the first thermal pad in contact with the focus ring and the thermally conductive member, the second thermal pad in contact with the thermally conductive member and the baseplate.

6. The pedestal assembly of claim 5, wherein the first thermal pad and the second thermal pad comprise a resilient material.

7. The pedestal assembly of claim 6, wherein the first thermal pad and the second thermal pad comprise an adhesive tape.

8. The pedestal assembly of claim 1, wherein the pedestal assembly further comprises an inner insulator ring at least partially surrounding the thermal conductive member and the baseplate.

9. The pedestal assembly of claim 5, wherein a thermal conductivity of the first thermal pad is different than a thermal conductivity of the second thermal pad.

10. The pedestal assembly of claim 5, wherein a thermal conductivity of the thermally conductive member is different than the thermal conductivity of the first thermal pad or the thermal conductivity of the second thermal pad.

11. The pedestal assembly of claim 1, wherein the baseplate defines one or more passages through which a fluid flows to adjust a temperature of the baseplate.

12. The pedestal assembly of claim 1, wherein the thermally conductive member is a ring comprised of aluminum.

13. The pedestal assembly of claim 5, wherein the baseplate is stepped such that the baseplate comprises a first portion that extends vertically above a second portion.

14. The pedestal assembly of claim 13, wherein the puck is disposed above the first portion of the baseplate.

15. The pedestal assembly of claim 14, wherein the second thermal pad is in contact with the second portion of the baseplate.

16. The pedestal assembly of claim 5, wherein the pedestal assembly comprises a fastener configured to provide a compression connection that compresses the second thermal pad between the thermally conductive member and the baseplate.

17. A plasma processing apparatus for processing a substrate, the apparatus comprising:
a processing chamber defining an interior space;
a pedestal assembly disposed within the interior space, the pedestal assembly comprising:
an inner insulator ring;
a baseplate surrounded at least in part by the inner insulator ring;
a puck configured to support the substrate;
a focus ring at least partially surrounding a periphery of the substrate when the substrate is positioned on the puck, the focus ring comprising a top surface and an opposing bottom surface;
a first thermal pad in contact with the bottom surface of the focus ring;
a second thermal pad in contact with the baseplate;
a thermally conductive member coupled between the first thermal pad and the second thermal pad;
wherein the first thermal pad, second thermal pad, and thermally conductive member form a heat path for conduction of heat from the focus ring to the baseplate; and
wherein the focus ring has a body and a protrusion extending from the body, the protrusion being disposed between the substrate and the puck when the substrate is supported by the puck, wherein a gap is defined between the puck and the protrusion of the substrate.

18. The plasma processing apparatus of claim 17, wherein the first thermal pad and the second thermal pad comprise a resilient material.

19. The plasma processing apparatus of claim 17, wherein the baseplate is stepped such that the baseplate comprises a first portion that extends vertically above a second portion; wherein the puck is disposed above the first portion of the baseplate; and wherein the second thermal pad is in contact with the second portion of the baseplate.

20. The pedestal assembly of claim 17, wherein the pedestal assembly comprises a fastener configured to provide a compression connection that compresses the second thermal pad between the thermally conductive member and the baseplate.
